(19) United States
(12) Patent Application Publication
(10) Pub. No.: US 2026/0322354 A1
(43) Pub. Date: Oct. 15, 2026

(54) BULK ACOUSTIC WAVE RESONATOR WITH CONDUCTIVE LAYER BETWEEN ELECTRODE AND PIEZOELECTRIC LAYER

(71) Applicant: Skyworks Global Pte. Ltd., Singapore (SG)

(72) Inventors: Kwang Jae Shin, Yongin-si (KR); Zongliang Cao, Irvine, CA (US); Alexandre Augusto Shirakawa, Cardiff by the Sea, CA (US); Reza Kasnavi, Solana Beach, CA (US)

(21) Appl. No.: 19/467,661

(22) Filed: Feb. 2, 2026

Related U.S. Application Data
(60) Provisional application No. 63/753,099, filed on Feb. 3, 2025.
(60) Provisional application No. 63/753,173, filed on Feb. 3, 2025.
(60) Provisional application No. 63/753,121, filed on Feb. 3, 2025.
(60) Provisional application No. 63/753,110, filed on Feb. 3, 2025.

(51) Int. Cl. H03H 9/17; H03H 9/02; H03H 9/05; H03H 9/13; H03H 9/54

(52) U.S. Cl. CPC H03H 9/175; H03H 9/02015; H03H 9/02086; H03H 9/0504; H03H 9/13; H03H 9/173; H03H 9/542

(57) ABSTRACT

A bulk acoustic wave device has a main active region and a frame region. The bulk acoustic wave includes a first electrode, a second electrode, a piezoelectric layer between the first electrode and the second electrode, and a conductive layer between the second electrode and the piezoelectric layer at least in the frame region. The conductive layer is electrically connected to the first electrode and electrically isolated from the second electrode.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

The disclosed technology relates to acoustic wave devices. Embodiments of this disclosure relate to bulk acoustic wave devices with an electric field blocking structure.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY

In some aspects, the techniques described herein relate to a bulk acoustic wave device having a main active region and a frame region, the bulk acoustic wave device including: a first electrode; a second electrode; a piezoelectric layer between the first electrode and the second electrode; and a conductive layer between the second electrode and the piezoelectric layer at least in the frame region, the conductive layer electrically connected to the first electrode and electrically isolated from the second electrode.

In some aspects, the techniques described herein relate to a bulk acoustic wave device wherein the frame region includes a frame structure, the frame structure includes a raised frame structure at least partially defined by the conductive layer.

In some aspects, the techniques described herein relate to a bulk acoustic wave device wherein the raised frame structure further includes a dielectric layer.

In some aspects, the techniques described herein relate to a bulk acoustic wave device wherein the frame structure further includes a recessed frame structure between the main active region and the raised frame structure.

In some aspects, the techniques described herein relate to a bulk acoustic wave device further including an acoustic wave reflector at least in the main active region.

In some aspects, the techniques described herein relate to a bulk acoustic wave device wherein the frame region at least partially overlaps the acoustic wave reflector.

In some aspects, the techniques described herein relate to a bulk acoustic wave device wherein the acoustic wave reflector includes an air cavity.

In some aspects, the techniques described herein relate to a bulk acoustic wave device wherein the acoustic wave reflector includes a Bragg reflector.

In some aspects, the techniques described herein relate to a bulk acoustic wave device wherein the conductive layer is in contact with the piezoelectric layer in the frame region and the second electrode is in contact with the piezoelectric layer in the main active region.

In some aspects, the techniques described herein relate to a bulk acoustic wave device having a main active region and a frame region, the bulk acoustic wave device including: a first electrode; a second electrode; a piezoelectric layer between the first electrode and the second electrode; and a conductive layer between the second electrode and the piezoelectric layer at least in the frame region, the conductive layer electrically isolated from the second electrode, the conductive layer and the first electrode having a first electrical polarity and the second electrode having a second electrical polarity.

In some aspects, the techniques described herein relate to a bulk acoustic wave device wherein the frame region includes a frame structure, the frame structure includes a raised frame structure at least partially defined by the conductive layer.

In some aspects, the techniques described herein relate to a bulk acoustic wave device wherein the frame structure further includes a recessed frame structure between the main active region and the raised frame structure.

In some aspects, the techniques described herein relate to a bulk acoustic wave device further including an acoustic wave reflector at least in the main active region.

In some aspects, the techniques described herein relate to a bulk acoustic wave device wherein the frame region at least partially overlaps the acoustic wave reflector.

In some aspects, the techniques described herein relate to a bulk acoustic wave device wherein the conductive layer is in contact with the piezoelectric layer in the frame region and the second electrode is in contact with the piezoelectric layer in the main active region.

In some aspects, the techniques described herein relate to an acoustic wave filter for filtering a radio frequency signal, the acoustic wave filter including: a bulk acoustic wave resonator structure of any preceding claim; and a plurality of additional acoustic wave resonators, the bulk acoustic wave resonator structure and the plurality of additional acoustic wave resonators configured to filter the radio frequency signal.

In some aspects, the techniques described herein relate to a multiplexer for filtering radio frequency signals, the multiplexer including: a first filter including a bulk acoustic wave resonator structure of any preceding claim; and a second filter coupled to the first filter at a common node.

In some aspects, the techniques described herein relate to a radio frequency module including: a filter including a bulk acoustic wave resonator structure of any preceding claim; radio frequency circuitry; and a package structure enclosing the filter and the radio frequency circuitry.

In some aspects, the techniques described herein relate to a radio frequency system including: an antenna; a filter including a bulk acoustic wave resonator structure of any preceding claim; and an antenna switch configured to selectively electrically connect the antenna and a signal path that includes the filter.

In some aspects, the techniques described herein relate to a wireless communication device including: a radio frequency front end including a filter that includes a bulk acoustic wave resonator structure of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a bulk acoustic wave resonator structure of any preceding claim.

In some aspects, the techniques described herein relate to a bulk acoustic wave device having a main active region and a frame region, the bulk acoustic wave device including: a first electrode; a second electrode; a piezoelectric layer between the first electrode and the second electrode; a conductive layer between the second electrode and the piezoelectric layer at least in the frame region, the conductive layer electrically connected to the first electrode; and a gas-gap between the conductive layer and the second electrode.

In some aspects, the techniques described herein relate to a bulk acoustic wave device wherein the gas-gap is an airgap.

In some aspects, the techniques described herein relate to a bulk acoustic wave device wherein the frame region includes a frame structure, the frame structure includes a raised frame structure at least partially defined by the conductive layer.

In some aspects, the techniques described herein relate to a bulk acoustic wave device wherein the raised frame structure further includes a dielectric layer.

In some aspects, the techniques described herein relate to a bulk acoustic wave device wherein the frame structure further includes a recessed frame structure between the main active region and the raised frame structure.

In some aspects, the techniques described herein relate to a bulk acoustic wave device further including an acoustic wave reflector at least in the main active region.

In some aspects, the techniques described herein relate to a bulk acoustic wave device wherein the frame region at least partially overlaps the acoustic wave reflector.

In some aspects, the techniques described herein relate to a bulk acoustic wave device wherein the acoustic wave reflector includes an air cavity.

In some aspects, the techniques described herein relate to a bulk acoustic wave device wherein the acoustic wave reflector includes a Bragg reflector.

In some aspects, the techniques described herein relate to a bulk acoustic wave device wherein the conductive layer is in contact with the piezoelectric layer in the frame region and the second electrode is in contact with the piezoelectric layer in the main active region.

In some aspects, the techniques described herein relate to a method of forming a bulk acoustic wave device having a main active region and a frame region, the method including: providing a first electrode; providing a piezoelectric layer over the first electrode; providing a conductive layer over the piezoelectric layer at least in the frame region and electrically connecting the conductive layer and the first electrode; providing a sacrificial layer over the conductive layer at least in the frame region; providing a second electrode over the sacrificial layer in the frame region and over the piezoelectric layer in the main active region; and removing the sacrificial layer to thereby form a gas-gap between the conductive layer and the second electrode.

In some aspects, the techniques described herein relate to a method wherein the gas-gap is an airgap.

In some aspects, the techniques described herein relate to a method wherein providing the conductive layer includes forming a raised frame structure.

In some aspects, the techniques described herein relate to a method further including forming an acoustic wave reflector at least in the main active region.

In some aspects, the techniques described herein relate to a method wherein forming the acoustic wave reflector includes forming an air cavity.

In some aspects, the techniques described herein relate to a method wherein forming the acoustic wave reflector includes forming a Bragg reflector.

In some aspects, the techniques described herein relate to a method wherein the conductive layer is in contact with the piezoelectric layer in the frame region and the second electrode is in contact with the piezoelectric layer in the main active region.

In some aspects, the techniques described herein relate to an acoustic wave filter for filtering a radio frequency signal, the acoustic wave filter including: a bulk acoustic wave resonator structure of any preceding claim; and a plurality of additional acoustic wave resonators, the bulk acoustic wave resonator structure and the plurality of additional acoustic wave resonators configured to filter the radio frequency signal.

In some aspects, the techniques described herein relate to a multiplexer for filtering radio frequency signals, the multiplexer including: a first filter including a bulk acoustic wave resonator structure of any preceding claim; and a second filter coupled to the first filter at a common node.

In some aspects, the techniques described herein relate to a radio frequency module including: a filter including a bulk acoustic wave resonator structure of any preceding claim; radio frequency circuitry; and a package structure enclosing the filter and the radio frequency circuitry.

In some aspects, the techniques described herein relate to a radio frequency system including: an antenna; a filter including a bulk acoustic wave resonator structure of any preceding claim; and an antenna switch configured to selectively electrically connect the antenna and a signal path that includes the filter.

In some aspects, the techniques described herein relate to a wireless communication device including: a radio frequency front end including a filter that includes a bulk acoustic wave resonator structure of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a bulk acoustic wave resonator structure of any preceding claim.

In some aspects, the techniques described herein relate to a bulk acoustic wave device having a main active region and a frame region, the bulk acoustic wave device including: a first electrode; a second electrode; a piezoelectric layer between the first electrode and the second electrode; a conductive layer between the second electrode and the piezoelectric layer at least in the frame region, the conductive layer electrically connected to the first electrode; and an insulating layer between the conductive layer and the second electrode.

In some aspects, the techniques described herein relate to a bulk acoustic wave device wherein the insulating layer includes oxide, nitride, or carbide.

In some aspects, the techniques described herein relate to a bulk acoustic wave device wherein the frame region includes a frame structure, the frame structure includes a raised frame structure at least partially defined by the conductive layer.

In some aspects, the techniques described herein relate to a bulk acoustic wave device wherein the raised frame structure further includes a dielectric layer.

In some aspects, the techniques described herein relate to a bulk acoustic wave device wherein the frame structure further includes a recessed frame structure between the main active region and the raised frame structure.

In some aspects, the techniques described herein relate to a bulk acoustic wave device further including an acoustic wave reflector at least in the main active region.

In some aspects, the techniques described herein relate to a bulk acoustic wave device wherein the frame region at least partially overlaps the acoustic wave reflector.

In some aspects, the techniques described herein relate to a bulk acoustic wave device wherein the acoustic wave reflector includes an air cavity.

In some aspects, the techniques described herein relate to a bulk acoustic wave device wherein the acoustic wave reflector includes a Bragg reflector.

In some aspects, the techniques described herein relate to a bulk acoustic wave device wherein the conductive layer is in contact with the piezoelectric layer in the frame region and the second electrode is in contact with the piezoelectric layer in the main active region.

In some aspects, the techniques described herein relate to a method of forming a bulk acoustic wave device having a main active region and a frame region, the method including: providing a first electrode; providing a piezoelectric layer over the first electrode; providing a conductive layer over the piezoelectric layer at least in the frame region and electrically connecting the conductive layer and the first electrode; providing an insulating layer over the conductive layer at least in the frame region; and providing a second electrode over the insulating layer in the frame region and over the piezoelectric layer in the main active region.

In some aspects, the techniques described herein relate to a method wherein providing the insulating layer includes depositing silicon oxide.

In some aspects, the techniques described herein relate to a method wherein providing the conductive layer includes forming a raised frame structure.

In some aspects, the techniques described herein relate to a method further including forming an acoustic wave reflector at least in the main active region.

In some aspects, the techniques described herein relate to a method wherein forming the acoustic wave reflector includes forming an air cavity.

In some aspects, the techniques described herein relate to a method wherein forming the acoustic wave reflector includes forming a Bragg reflector.

In some aspects, the techniques described herein relate to a method wherein the conductive layer is in contact with the piezoelectric layer in the frame region and the second electrode is in contact with the piezoelectric layer in the main active region.

In some aspects, the techniques described herein relate to an acoustic wave filter for filtering a radio frequency signal, the acoustic wave filter including: a bulk acoustic wave resonator structure of any preceding claim; and a plurality of additional acoustic wave resonators, the bulk acoustic wave resonator structure and the plurality of additional acoustic wave resonators configured to filter the radio frequency signal.

In some aspects, the techniques described herein relate to a multiplexer for filtering radio frequency signals, the multiplexer including: a first filter including a bulk acoustic wave resonator structure of any preceding claim; and a second filter coupled to the first filter at a common node.

In some aspects, the techniques described herein relate to a radio frequency module including: a filter including a bulk acoustic wave resonator structure of any preceding claim; radio frequency circuitry; and a package structure enclosing the filter and the radio frequency circuitry.

In some aspects, the techniques described herein relate to a radio frequency system including: an antenna; a filter including a bulk acoustic wave resonator structure of any preceding claim; and an antenna switch configured to selectively electrically connect the antenna and a signal path that includes the filter.

In some aspects, the techniques described herein relate to a wireless communication device including: a radio frequency front end including a filter that includes a bulk acoustic wave resonator structure of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a bulk acoustic wave resonator structure of any preceding claim.

In some aspects, the techniques described herein relate to a bulk acoustic wave device having a main active region and a frame region, the bulk acoustic wave device including: a first electrode; a second electrode; a piezoelectric layer between the first electrode and the second electrode; a first conductive layer in a first portion of the frame region, the first conductive layer electrically connected to the first electrode and the piezoelectric layer in the first portion of the frame region being positioned between the first electrode and the first conductive layer; and a second conductive layer in a second portion of the frame region, the second conductive layer electrically connected to the second electrode and the piezoelectric layer in the second portion of the frame region being positioned between the second electrode and the second conductive layer.

In some aspects, the techniques described herein relate to a bulk acoustic wave device wherein the first portion of the frame region includes a first frame structure, and the second portion of the frame region includes a second frame structure.

In some aspects, the techniques described herein relate to a bulk acoustic wave device wherein the first frame structure includes the first conductive layer, and the second frame structure includes the second conductive layer.

In some aspects, the techniques described herein relate to a bulk acoustic wave device wherein the first frame structure includes a thin portion of the second electrode thinner than a thickness of the second electrode in the main active region.

In some aspects, the techniques described herein relate to a bulk acoustic wave device wherein the first frame structure includes a first insulating material positioned between the second electrode and the first conductive layer, and the second frame structure includes a second insulating material positioned between the first electrode and the second conductive layer.

In some aspects, the techniques described herein relate to a bulk acoustic wave device further including an acoustic wave reflector at least in the main active region.

In some aspects, the techniques described herein relate to a bulk acoustic wave device wherein the frame region at least partially overlaps the acoustic wave reflector.

In some aspects, the techniques described herein relate to a bulk acoustic wave device wherein the acoustic wave reflector includes an air cavity.

In some aspects, the techniques described herein relate to a bulk acoustic wave device wherein the acoustic wave reflector includes a Bragg reflector.

In some aspects, the techniques described herein relate to a bulk acoustic wave device wherein the first conductive layer and the second conductive layer are in contact with the piezoelectric layer in the frame region and the second electrode is in contact with the piezoelectric layer in the main active region.

In some aspects, the techniques described herein relate to a bulk acoustic wave device further includes an insulator between the first electrode and the second conductive layer.

In some aspects, the techniques described herein relate to a bulk acoustic wave device having a main active region and a frame region, the bulk acoustic wave device including: a piezoelectric layer having a first side and a second side opposite the first side; a first electrode on the first side of the piezoelectric layer; a second electrode on the second side of the piezoelectric layer; a first conductive layer on the second side of the piezoelectric layer and electrically connected to the first electrode; and a second conductive layer on the first side of the piezoelectric layer and electrically connected to the second electrode.

In some aspects, the techniques described herein relate to a bulk acoustic wave device further including an insulator on the first side of the piezoelectric layer electrically isolating the first electrode and the second conductive layer.

In some aspects, the techniques described herein relate to a bulk acoustic wave device wherein a first portion of the frame region includes a first frame structure, and a second portion of the frame region includes a second frame structure.

In some aspects, the techniques described herein relate to a bulk acoustic wave device wherein the first frame structure includes the first conductive layer, and the second frame structure includes the second conductive layer.

In some aspects, the techniques described herein relate to a bulk acoustic wave device further including an acoustic wave reflector at least in the main active region.

In some aspects, the techniques described herein relate to a multiplexer for filtering radio frequency signals, the multiplexer including: a first filter including a bulk acoustic wave resonator structure of any preceding claim; and a second filter coupled to the first filter at a common node.

In some aspects, the techniques described herein relate to a radio frequency module including: a filter including a bulk acoustic wave resonator structure of any preceding claim; radio frequency circuitry; and a package structure enclosing the filter and the radio frequency circuitry.

In some aspects, the techniques described herein relate to a radio frequency system including: an antenna; a filter including a bulk acoustic wave resonator structure of any preceding claim; and an antenna switch configured to selectively electrically connect the antenna and a signal path that includes the filter.

In some aspects, the techniques described herein relate to a wireless communication device including: a radio frequency front end including a filter that includes a bulk acoustic wave resonator structure of any preceding claim; an antenna coupled to the radio frequency front end; a transceiver in communication with the radio frequency front end; and a baseband system in communication with the transceiver.

In some aspects, the techniques described herein relate to a method of radio frequency signal processing, the method including: receiving a radio frequency signal via at least an antenna; and filtering the radio frequency signal with a filter that includes a bulk acoustic wave resonator structure of any preceding claim.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a BAW device.

FIG. 1B is a simulated frequency response graph showing S11 scattering parameters and Y11 admittance parameters of the BAW device of FIG. 1A.

FIG. 2A is a schematic cross-sectional side view of a BAW device according to an embodiment.

FIG. 2B is an enlarged view of the BAW device of FIG. 2A.

FIG. 2C is a simulated frequency response graph showing S11 scattering parameters and Y11 admittance parameters of the BAW device of FIG. 2A.

FIG. 3 is a schematic cross-sectional side view of a BAW device according to an embodiment.

FIG. 4 is a schematic cross-sectional side view of a raised frame structure that includes an electric field blocking structure according to an embodiment.

FIG. 5 is a schematic cross-sectional side view of a raised frame structure that includes an electric field blocking structure according to another embodiment.

FIG. 6A is a schematic cross-sectional side view of a BAW device according to an embodiment.

FIG. 6B is a schematic cross-sectional side view of a BAW device according to another embodiment.

FIG. 7A is a schematic diagram of a ladder filter that includes an acoustic wave resonator according to an embodiment.

FIG. 7B is schematic diagram of an acoustic wave filter.

FIGS. 8A, 8B, 8C, and 8D are schematic diagrams of multiplexers that includes an acoustic wave resonator according to an embodiment.

FIGS. 9, 10, and 11 are schematic block diagrams of modules that include a filter with an acoustic wave device according to an embodiment.

FIG. 12 is a schematic block diagram of a wireless communication device that includes a filter with an acoustic wave device according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices can include frame structures, such as raised frame structures and/or recessed frame structures.

A BAW device can include a pair of electrodes (a first electrode and a second electrode) and a piezoelectric layer positioned between the first and second electrodes. A region in which the pair of electrodes and the piezoelectric layer overlap over an acoustic reflector can define an acoustically active region. A frame structure, such as a raised frame and/or a recessed frame, can be positioned at an edge portion within the acoustically active region to reduce lateral energy leakage from the acoustically active region. However, a raised frame structure can create a resonance or a thickness extension mode at a frequency that is below a resonant frequency of the acoustically active region of the BAW device when the raised frame structure overlaps with the pair of electrodes and the piezoelectric layer over the acoustic reflector. This resonance can be below a main resonant frequency of the BAW device. A resonance associated with the raised frame structure can be referred to as a frame mode, and more specifically a raised frame mode. The raised frame mode can be undesirable in certain applications.

Various embodiments disclosed herein relate to bulk acoustic wave devices with a structure that reduces a raised frame mode. A bulk acoustic wave device can have a main active region and a frame region. The bulk acoustic wave device can include a first electrode, a second electrode, a piezoelectric layer between the first electrode and the second electrode, and an electric field blocking structure. The electric field blocking structure can include a conductive layer between the second electrode and the piezoelectric layer at least in the frame region. The conductive layer is electrically isolated from the second electrode. The conductive layer can be electrically connected to the first electrode. The conductive layer and the first electrode can have a first electrical polarity and the second electrode can have a second electrical polarity different from the first electrical polarity. The electric field blocking structure can include a gas-gap or an insulator between the conductive layer and the second electrode to electrically isolate the conductive layer and the second electrode. The gas-gap can be an airgap and the insulator can be a dielectric layer, such as a silicon oxide layer (e.g., a silicon dioxide (SiO2) layer). The electric field blocking structure can prevent or suppress formation of the thickness extension mode or the frame mode in the frame region of the BAW device.

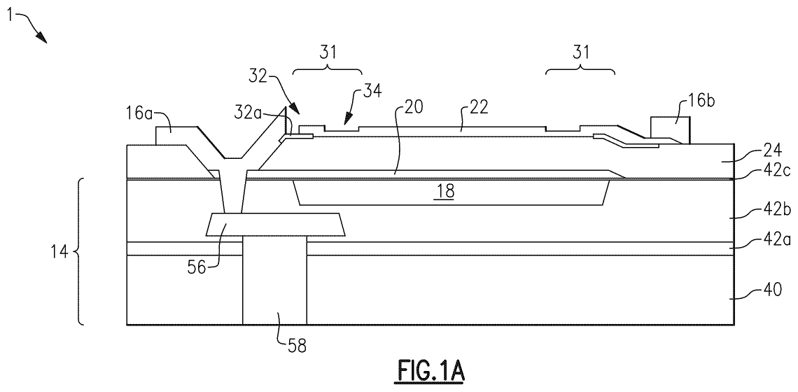

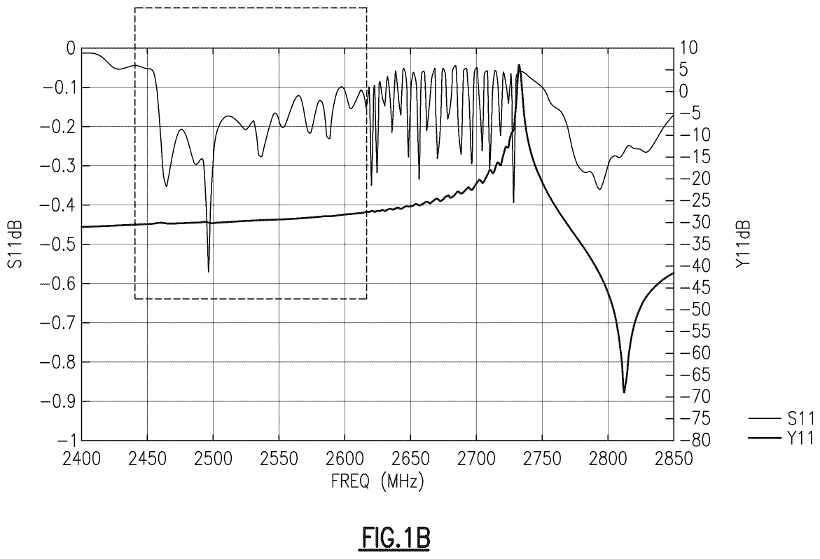

FIG. 1A is a schematic cross-sectional side view of a BAW device 1. The BAW device 1 includes a support structure 14, a first interconnect structure 16a, a second interconnect structure 16b, a cavity 18, a first electrode 20 connected to the first interconnect structure 16a, a second electrode 22 connected to the second interconnect structure 16b, and a piezoelectric layer 24 between the first and second electrodes 20, 22. A region where the cavity, first electrode 20, the second electrode 22, and the piezoelectric layer 24 overlap can be referred to an acoustically active region. The BAW device 1 also includes a frame structure 31 in a frame region. The frame structure 31 can include a raised frame structure 32 and/or a recessed frame structure 34. The raised frame structure 32 includes an oxide layer 32a.

The support structure 14 includes a support substrate 40 and an intermediate layer 42 between the support substrate and the first electrode 20. The intermediate layer 42 includes one or more of a seed layer, a trap rich layer, a passivation layer, or one or more other suitable functional layers. The intermediate layer structure 42 can include a trap-rich layer 42a, a passivation layer 42b and a dielectric layer 42c. The support structure 14 can also include conductive structures 56, 58.

The raised frame structure 32 can create a resonance or a thickness extension mode at a frequency that is below a resonant frequency of the acoustically active region of the BAW device 1. This resonance can be below a main resonant frequency of the BAW device 1. A resonance associated with the raised frame structure 32 can be referred to as a frame mode, and more specifically a raised frame mode. The raised frame mode can be undesirable in certain applications.

FIG. 1B is a simulated frequency response graph showing S11 scattering parameters and Y11 admittance parameters of the BAW device 1 of FIG. 1A. The graph of FIG. 1B shows the raised frame mode in the region indicated with a red dashed-line area. The raised frame mode in the frequency response outside of the operating frequency (e.g., out-of-band signals) can be a critical issue for, for example, multi-filter designs. The out-of-band signals can cause, for example, signal interference, impact on insertion loss (IL), out-of-band rejection, etc. Therefore, it can be technically challenging to reduce lateral energy leakage from the acoustically active region while achieving no or a relatively small raised frame mode.

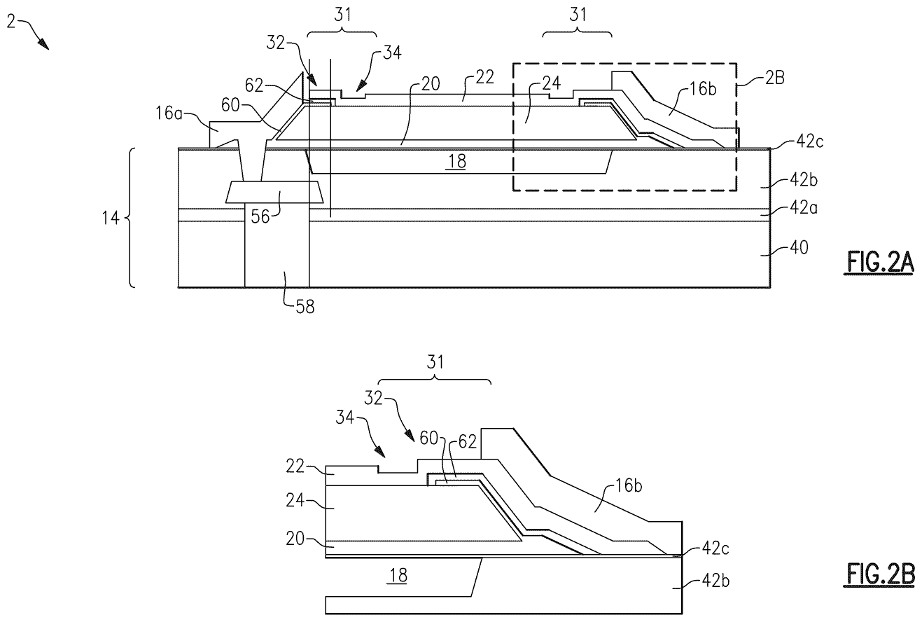

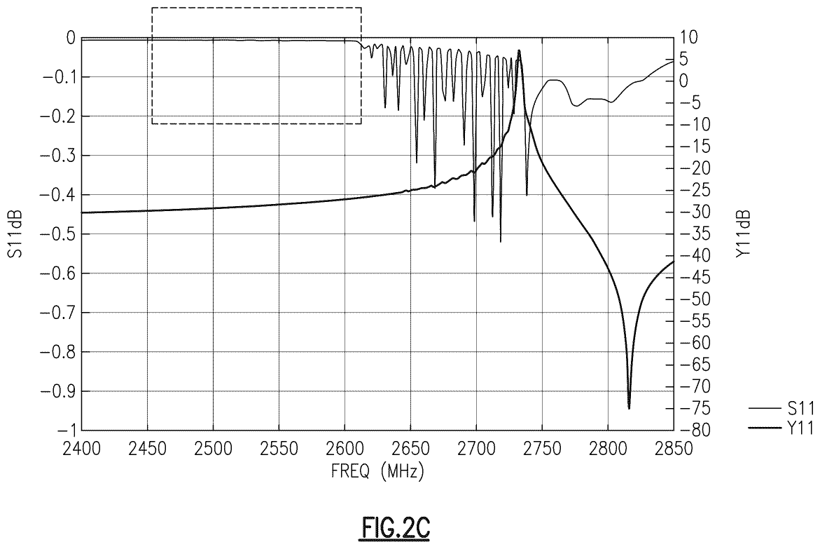

FIG. 2A is a schematic cross-sectional side view of a BAW device 2 according to an embodiment. FIG. 2B is an enlarged view of the BAW device 2 of FIG. 2A. The BAW device 2 can include a support structure 14, a first interconnect structure 16a, a second interconnect structure 16b, a cavity 18, a first electrode 20 connected to the first interconnect structure 16a, a second electrode 22 connected to the second interconnect structure 16b, and a piezoelectric layer 24 between the first and second electrodes 20, 22. A region where the cavity, first electrode 20, the second electrode 22, and the piezoelectric layer 24 overlap can be referred to an acoustically active region. The BAW device 2 can also include a frame structure 31 in a frame region. The frame structure 31 can include a raised frame structure 32 and/or a recessed frame structure 34. A region in the acoustically active region that does not overlap with the frame region can be referred to as a main active region.

The BAW device 2 can also include an electric field blocking structure. The electric field blocking structure can include a conductive layer 60 between the second electrode 22 and the piezoelectric layer 24 at least in the frame region. The conductive layer 60 is electrically isolated from the second electrode 22. The conductive layer 60 can be electrically connected to the first electrode 20 in some applications. The conductive layer 60 and the first electrode 20 can have a first electrical polarity and the second electrode 24 can have a second electrical polarity different from the first electrical polarity. The electric field blocking structure can include an insulator 62 (e.g., a gas-gap or a dielectric layer) between the conductive layer 60 and the second electrode 22 to electrically isolate the conductive layer 60 and the second electrode 22. For example, the gas-gap can be an airgap and the dielectric layer can be a silicon oxide layer (e.g., a silicon dioxide (SiO2) layer). The silicon oxide layer may include an additive, such as carbon or nitride.

The raised frame structure 32 can include at least a portion of the electric field blocking structure that includes the conductive layer 60 and the insulator 62. In some other embodiments, the raised frame structure 32 can include one or more additional layers (not shown). For example, the raised frame structure 32 can include an additional conductive layer or an additional dielectric layer. Because the conductive layer 60 and the first electrode 20 have the same electrical polarity, there can be no or substantially no active piezoelectric layer vibration in the frame region. Thus, the electric field blocking structure can reduce lateral energy leakage from the acoustically active region and prevent or suppress formation of the thickness extension mode or the frame mode in the frame region of the BAW device 2. The electric field blocking structure that includes the conductive layer 60 and the insulator 62 can achieve such benefits without modifying the piezoelectric layer 24.

An Example method of forming the BAW 2 with the electric field blocking structure will be described. The method can include providing the first electrode 20, providing the piezoelectric layer 24 over the first electrode 20, and providing a conductive layer 60 over the piezoelectric layer 24 at least in the frame region. The conductive layer 60 can be connected to the first electrode 20. The method can also include, when the gas-gap is used as the insulator 62, providing a sacrificial layer (not shown) over the conductive layer 60 at least in the frame region and providing the second electrode 22 over the sacrificial layer in the frame region and over the piezoelectric layer 24 in the main active region. The method can further include removing the sacrificial layer to thereby form a gas-gap (e.g., an airgap) between the conductive layer 60 and the second electrode 22. The method can also include, when a physical layer, such as a dielectric layer, is used as the insulator 62, providing the insulator 62 over the conductive layer 60 at least in the frame region and providing the second electrode 22 over the insulator 62 in the frame region and over the piezoelectric layer 24 in the main active region.

The cavity 18 (e.g., an air cavity) can be formed between the support substrate 40 and the first electrode 20. Heat generated by the piezoelectric layer 24 can flow laterally over the cavity 18 to a heat dissipation path where the BAW device 18 is free from the cavity 18 between the piezoelectric layer 23 and the support structure 14. The cavity 18 is an example of an acoustic reflector. The BAW device 2 can include a film bulk acoustic wave resonator (FBAR). In some other embodiments, there can be a solid acoustic mirror in place of the cavity 18 and such a BAW device can be a BAW solidly mounted resonator (SMR).

The first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region of the BAW device 2.

The piezoelectric layer 24 can include a suitable material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the piezoelectric layer 24 can be AlN based layer doped with Sc. Doping the piezoelectric layer 24 can adjust the resonant frequency. Doping the piezoelectric layer 24 can increase the electromechanical coupling coefficient (kt2) of the BAW device 2. Doping to increase the kt2 can be advantageous at higher frequencies where kt2 can be degraded. Doping to increase the coupling coefficient k2 can be advantageous for wide band devices and/or high frequency devices where the coupling coefficient k2 may be limited due to a thin resonator stack including a relatively thin piezoelectric layer thickness.

The conductive layer 60 can have any suitable conductive material. In some embodiments, the materials of the conductive layer 60 and the first and/or second electrode(s) can be the same. In certain applications it can be beneficial to include, in the conductive layer 60, a material that has a relatively high mass density. For instance, the conductive layer 60 can include molybdenum (Mo), tungsten (W), ruthenium (Ru), the like, or any suitable alloy thereof. In some embodiments, the insulator 62 can include a dielectric material with a relatively high density. The density of the insulator 62 can be similar to or heavier than, for example, the density of the first electrode 20 or the second electrode 22. In some embodiments, the conductive layer 60 can have a tapered edge. The tapered edge of conductive layer 60 may have a taper angle that is less than 90° or less than 45°.

In some embodiments, the recessed frame structure 34 can be defined by a thin portion of the second electrode 22. For example, the second electrode 22 can have a first thickness in the main active region and a second thickness that is thinner than the first thickness in a recessed frame region of the frame region to define the recessed frame structure 34.

The intermediate layer structure 42 can include a trap-rich layer 42a, a passivation layer 42b and a dielectric layer 42c. The support structure 14 can also include conductive structures 56, 58. The conductive structures 56, 58 can be thermally conductive and/or electrically conductive. The conductive structures 56, 58 can be configured to dissipate heat generated by the BAW device 2.

In some embodiments, the BAW device 2 can include a temperature compensation layer (not shown). The temperature compensation layer can bring the TCF of the BAW device 2 closer to zero. The temperature compensation layer can have a positive temperature coefficient of elasticity (TCE). The temperature compensation layer can be in physical contact with the piezoelectric layer 24. For example, the temperature compensation layer can be positioned (1) between the piezoelectric layer 24 and the second electrode 22, (2) between the piezoelectric layer 24 and the first electrode 20, (3) embedded within the piezoelectric layer 24, (4) embedded within an electrode 20 and/or 22, or (5) any suitable combination of (1) to (4).

FIG. 2C is a simulated frequency response graph showing S11 scattering parameters and Y11 admittance parameters of the BAW device 2 of FIG. 2A. The graph of FIG. 2C shows that the raised frame mode that is present in FIG. 1B is suppressed or removed. The simulation results of FIG. 2C indicate that the field blocking structure that includes the conductive layer 60 and the insulator 62 can prevent or suppress formation of the thickness extension mode or the frame mode in the frame region of the BAW device.

The BAW device 2 of FIG. 2A is an example of a film bulk acoustic wave resonator (FBAR). In some other embodiments, there can be a solid acoustic mirror in place of the cavity 18 and such a BAW device can be a BAW solidly mounted resonator (SMR).

FIG. 3 is a schematic cross-sectional side view of a BAW device 3 according to an embodiment. The BAW device 3 is an example of a BAW solidly mounted resonator (SMR). Unless otherwise noted, the components of the BAW device 3 shown in FIG. 3 may be structurally and/or functionally the same as or generally similar to like components disclosed herein.

In place of the cavity 18 in the BAW device 2, the BAW device 3 includes a solid acoustic mirror 78 between the support substrate 40 and the first electrode 20. The illustrated acoustic mirror 78 includes acoustic Bragg reflectors. The illustrated acoustic Bragg reflectors can include alternating low impedance layers 78a and high impedance layers 78b. As an example, the Bragg reflectors can include alternating silicon dioxide layers as low impedance layers 78a and tungsten layers as high impedance layers 78b. Any other suitable features of an SMR can alternatively or additionally be implemented. Any other suitable features of BAW devices disclosed herein can be implemented in a BAW SMR.

As with the BAW device 2, the BAW device 3 can include an electric field blocking structure. The electric field blocking structure can include a conductive layer 60 between the second electrode 22 and the piezoelectric layer 24 at least in the frame region. The conductive layer 60 is electrically isolated from the second electrode 22. The conductive layer 60 can be electrically connected to the first electrode 20 in some applications. The conductive layer 60 and the first electrode 20 can have a first electrical polarity and the second electrode 24 can have a second electrical polarity different from the first electrical polarity. The electric field blocking structure can include an insulator 62 (e.g., a gas-gap or a dielectric layer) between the conductive layer 60 and the second electrode 22 to electrically isolate the conductive layer 60 and the second electrode 22. For example, the gas-gap can be an airgap and the dielectric layer can be a silicon oxide layer (e.g., a silicon dioxide (SiO2) layer). The silicon oxide layer may include an additive, such as carbon or nitride.

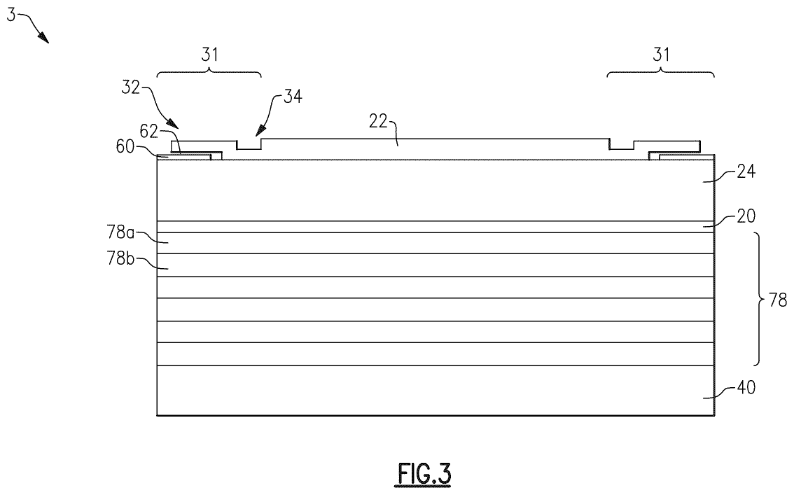

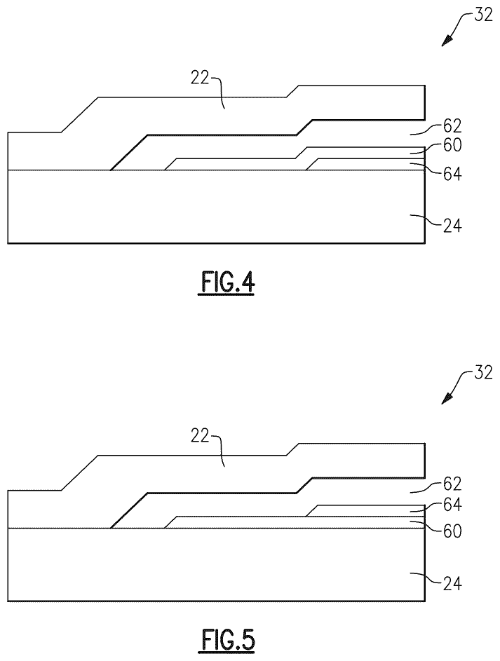

As noted herein, the raised frame structure 32 that includes at least a portion of the electric field blocking structure can include one or more additional layers (see FIGS. 4 and 5). Such additional layer(s) may add mass in the frame area to further reduce lateral energy leakage from the acoustically active region

FIG. 4 is a schematic cross-sectional side view of a raised frame structure 32 that includes an electric field blocking structure according to an embodiment. FIG. 5 is a schematic cross-sectional side view of a raised frame structure 32 that includes an electric field blocking structure according to another embodiment. Unless otherwise noted, the components shown in FIGS. 4 and 5 may be structurally and/or functionally the same as or generally similar to like components disclosed herein.

The electric field blocking structure shown in FIG. 4 includes an additional layer 64 between the conductive layer 60 and the piezoelectric layer 24. The electric field blocking structure shown in FIG. 5 includes an additional layer 64 between the conductive layer 60 and the insulator 62. The additional layer 64 can be a conductive layer or a dielectric layer.

The conductive layer 60 of the electric field blocking structures disclosed herein can be connected to the first electrode 20 or the second electrode 22 depending on the location of which the conductive layer 60 is positioned. The conductive layer 60 can be positioned at any suitable locations to block electric field formation in the frame region of the piezoelectric layer 24.

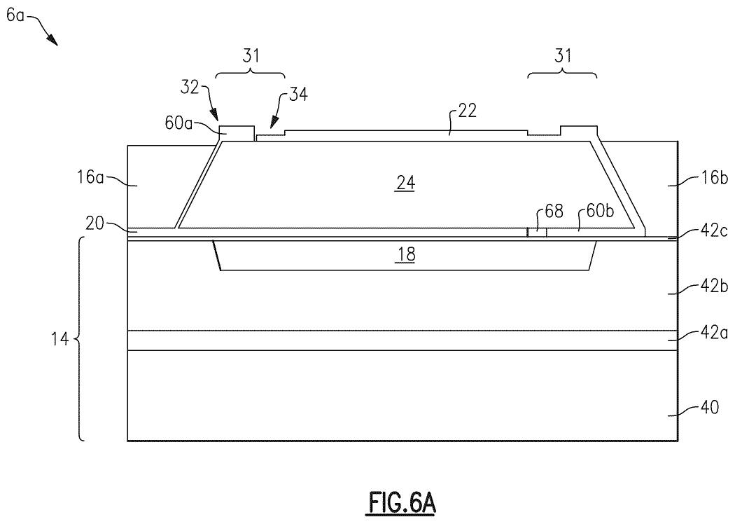

FIG. 6A is a schematic cross-sectional side view of a BAW device 6a according to an embodiment. Unless otherwise noted, the components of the BAW device 6a shown in FIG. 6A may be structurally and/or functionally the same as or generally similar to like components disclosed herein.

The BAW device 6a can include a support structure 14, a first interconnect structure 16a, a second interconnect structure 16b, a cavity 18, a first electrode 20 connected to the first interconnect structure 16a, a second electrode 22 connected to the second interconnect structure 16b, and a piezoelectric layer 24 between the first and second electrodes 20, 22. A region where the cavity, first electrode 20, the second electrode 22, and the piezoelectric layer 24 overlap can be referred to an acoustically active region. The BAW device 6a can also include a frame structure 31 in a frame region. The frame structure 31 can include a raised frame structure 32 and/or a recessed frame structure 34. A region in the acoustically active region that does not overlap with the frame region can be referred to as a main active region.

The BAW device 6a can also include an electric field blocking structure. The electric field blocking structure can include a first conductive layer 60a in a first portion of the frame region 31. The first conductive layer 60a can be electrically connected to the first electrode 20. The piezoelectric layer 24 in the first portion of the frame region 31 can be positioned between the first electrode 20 and the first conductive layer 60a. The electric field blocking structure can include a second conductive layer 60b in a second portion of the frame region 31. The second conductive layer 60b can be electrically connected to the second electrode 22. There can be a gap 68 between the second conductive layer 60b and the first electrode 20. The gap 68 can be filled with an insulating material (e.g., oxide, nitride, or carbide), or the gap can be a gas-gap (e.g., an airgap). The piezoelectric layer 24 in the second portion of the frame region 31 can be positioned between the second electrode 22 and the second conductive layer 60b. The first conductive layer 60a and the first electrode 20 can have a first electrical polarity and the second conductive layer 60b and the second electrode 24 can have a second electrical polarity different from the first electrical polarity. By having the same electrical polarity between the first electrode 20 and the first conductive layer 60a in the first portion of the frame region 31, there can be no or substantially no acoustic vibration in the piezoelectric layer 24 in the first portion of the frame region 31. Likewise, by having the same electrical polarity between the second electrode 22 and the second conductive layer 60b in the second portion of the frame region 31, there can be no or substantially no acoustic vibration in the piezoelectric layer 24 in the first portion of the frame region 31. The raised frame structure 32 can include at least a portion of the electric field blocking structure that includes the first conductive layer 60a and the second conductive layer 60b. Thus, the electric field blocking structure can reduce lateral energy leakage from the acoustically active region and prevent or suppress formation of the thickness extension mode or the frame mode in the frame region of the BAW device 6a. The electric field blocking structure that includes the first conductive layer 60a and the second conductive layer 60b can achieve such benefits without modifying the piezoelectric layer 24.

FIG. 6B is a schematic cross-sectional side view of a BAW device 6b according to an embodiment. Unless otherwise noted, the components of the BAW device 6b shown in FIG. 6B may be structurally and/or functionally the same as or generally similar to like components disclosed herein.

The BAW device 6b of FIG. 6B is generally similar to the BAW device 6a of FIG. 6A, except that the recessed frame structure 34 of FIG. 6B includes a different material from the second electrode 22. The recessed frame structure 34 can include a material that has a mass density less than a mass density of the material of the second electrode 22. In some embodiments, the recessed frame structure 34 can include the gap 68 between the second conductive layer 60b and the first electrode 20. A first portion of the frame region 31 (e.g., the left side in FIG. 6B) can include the raised frame structure 32 and a recessed frame structure 31 that has an insulator positioned between the second electrode 22 and the first conductive layer 60a, and a second portion of the frame structure 31 (e.g., the right side in FIG. 6B) can include the raised frame structure 32 and a recessed frame structure 31 that has an insulator positioned between the first electrode 20 and the second conductive layer 60b.

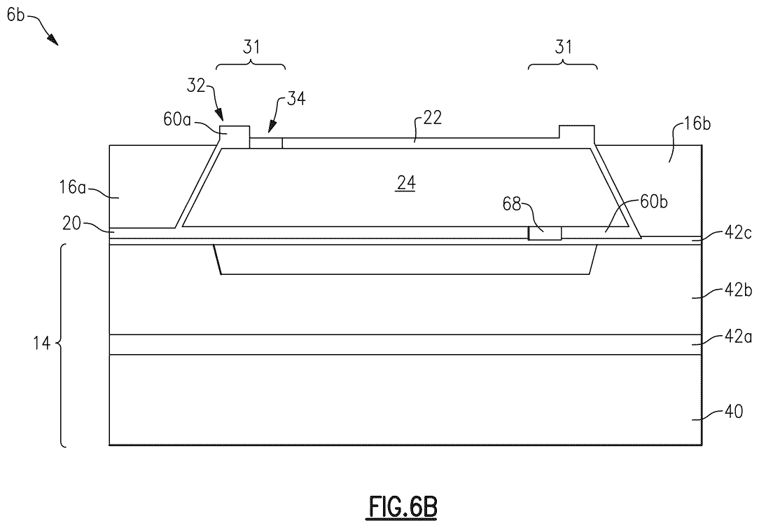

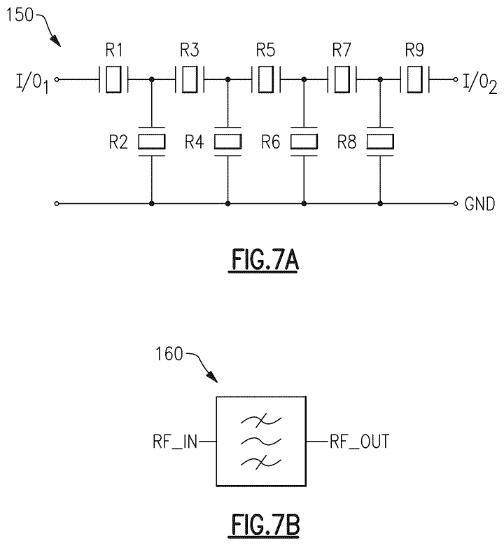

Acoustic wave devices disclosed herein can be implemented as acoustic wave resonators in a variety of filters. Such filters can be arranged to filter a radio frequency signal. Acoustic wave devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 7A.

FIG. 7A is a schematic diagram of a ladder filter 150 that includes an acoustic wave resonator according to an embodiment. The ladder filter 150 is an example topology that can implement a band pass filter formed of acoustic wave resonators. In a band pass filter with a ladder filter topology, the shunt resonators can have lower resonant frequencies than the series resonators. The ladder filter 150 can be arranged to filter a radio frequency signal. As illustrated, the ladder filter 150 includes series acoustic wave resonators R1 R3, R5, R7, and R9 and shunt acoustic wave resonators R2, R4, R6, and R8 coupled between a first input/output port I/O1 and a second input/output port I/O2. Any suitable number of series acoustic wave resonators can be in included in a ladder filter. Any suitable number of shunt acoustic wave resonators can be included in a ladder filter. The first input/output port I/O1 can be a transmit port and the second input/output port I/O2 can be an antenna port. Alternatively, first input/output port I/O1 can be a receive port and the second input/output port I/O2 can be an antenna port. One or more of the acoustic wave resonators of the ladder filter 150 can include an acoustic wave device including a silicon oxynitride layer in accordance with any suitable principles and advantages disclosed herein. All acoustic resonators of the ladder filter 150 can include a silicon oxynitride layer in accordance with any suitable principles and advantages disclosed herein in certain applications.

A filter that includes an acoustic wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

FIG. 7B is schematic diagram of an acoustic wave filter 160. The acoustic wave filter 160 can include the acoustic wave resonators of the ladder filter 150. The acoustic wave filter 160 is a band pass filter. The acoustic wave filter 160 is arranged to filter a radio frequency signal. The acoustic wave filter 160 includes one or more acoustic wave devices coupled between a first input/output port RF_IN and a second input/output port RF_OUT. The acoustic wave filter 160 includes an acoustic wave resonator according to an embodiment.

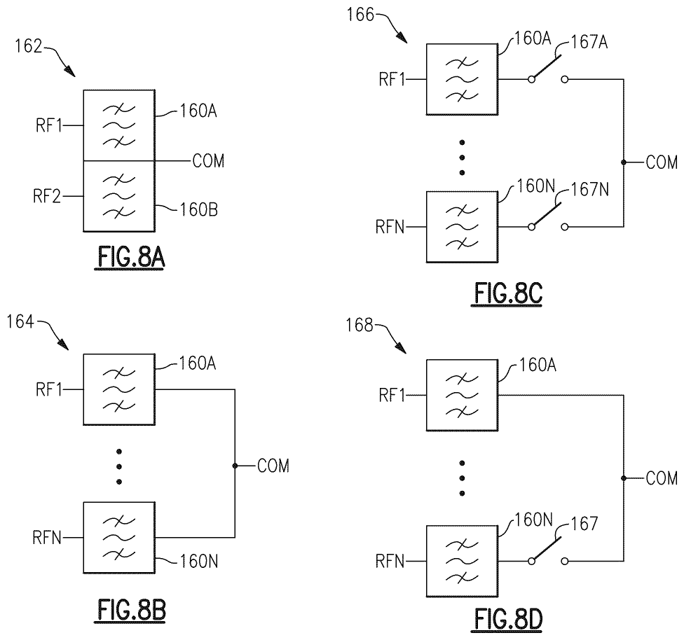

The acoustic wave devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 8A to 8D. Any suitable principles and advantages of these multiplexers can be implemented together with each other.

FIG. 8A is a schematic diagram of a duplexer 162 that includes an acoustic wave filter according to an embodiment. The duplexer 162 includes a first filter 160A and a second filter 160B coupled to together at a common node COM. One of the filters of the duplexer 162 can be a transmit filter and the other of the filters of the duplexer 162 can be a receive filter. In some other instances, such as in a diversity receive application, the duplexer 162 can include two receive filters. Alternatively, the duplexer 162 can include two transmit filters. The common node COM can be an antenna node.

The first filter 160A is an acoustic wave filter arranged to filter a radio frequency signal. The first filter 160A includes one or more acoustic wave resonators coupled between a first radio frequency node RF1 and the common node COM. The first radio frequency node RF1 can be a transmit node or a receive node. The first filter 160A includes an acoustic wave resonator in accordance with any suitable principles and advantages disclosed herein.

The second filter 160B can be any suitable filter arranged to filter a second radio frequency signal. The second filter 160B can be, for example, an acoustic wave filter, an acoustic wave filter that includes an acoustic wave resonator with at least one silicon oxynitride layer in accordance with any suitable principles and advantages disclosed herein, an LC filter, a hybrid acoustic wave LC filter, or the like. The second filter 160B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 8B is a schematic diagram of a multiplexer 164 that includes an acoustic wave filter according to an embodiment. The multiplexer 164 includes a plurality of filters 160A to 160N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 160A to 160N each have a fixed electrical connection to the common node COM. This can be referred to as hard multiplexing or fixed multiplexing. Filters have fixed electrical connections to the common node in hard multiplexing applications.

The first filter 160A is an acoustic wave filter arranged to filter a radio frequency signal. The first filter 160A can include one or more acoustic wave devices coupled between a first radio frequency node RF1 and the common node COM. The first radio frequency node RF1 can be a transmit node or a receive node. The first filter 160A includes an acoustic wave resonator in accordance with any suitable principles and advantages disclosed herein. The other filter(s) of the multiplexer 164 can include one or more acoustic wave filters, one or more acoustic wave filters that include an acoustic wave resonator in accordance with any suitable principles and advantages disclosed herein, one or more LC filters, one or more hybrid acoustic wave LC filters, the like, or any suitable combination thereof.

FIG. 8C is a schematic diagram of a multiplexer 166 that includes an acoustic wave filter according to an embodiment. The multiplexer 166 is like the multiplexer 164 of FIG. 8B, except that the multiplexer 166 implements switched multiplexing. In switched multiplexing, a filter is coupled to a common node via a switch. In the multiplexer 166, the switches 167A to 167N can selectively electrically connect respective filters 160A to 160N to the common node COM. For example, the switch 167A can selectively electrically connect the first filter 160A the common node COM via the switch 167A. Any suitable number of the switches 167A to 167N can electrically a respective filter 160A to 160N to the common node COM in a given state. Similarly, any suitable number of the switches 167A to 167N can electrically isolate a respective filter 160A to 160N to the common node COM in a given state. The functionality of the switches 167A to 167N can support various carrier aggregations.

FIG. 8D is a schematic diagram of a multiplexer 168 that includes an acoustic wave filter according to an embodiment. The multiplexer 168 illustrates that a multiplexer can include any suitable combination of hard multiplexed and switched multiplexed filters. One or more acoustic wave devices in accordance with any suitable principles and advantages disclosed herein can be included in a filter (e.g., the filter 160A) that is hard multiplexed to the common node COM of the multiplexer 168. Alternatively or additionally, one or more acoustic wave devices in accordance with any suitable principles and advantages disclosed herein can be included in a filter (e.g., the filter 160N) that is switch multiplexed to the common node COM of the multiplexer 168.

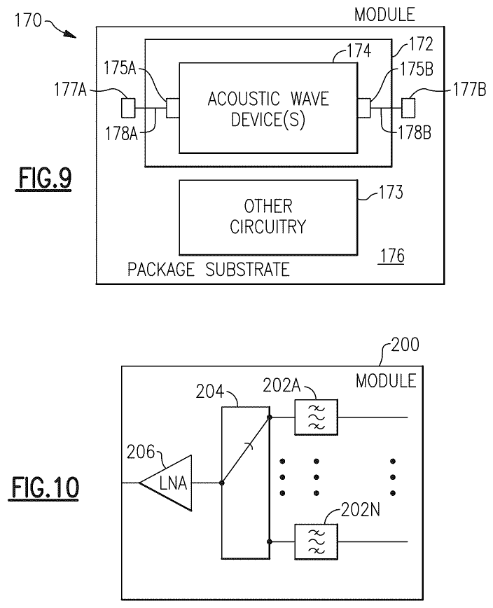

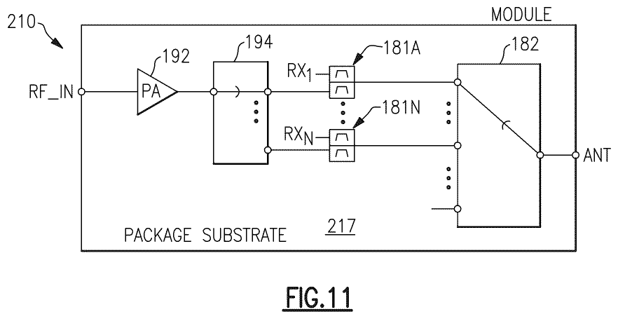

Acoustic wave devices disclosed herein can be implemented in a variety of packaged modules. Some example packaged modules will now be disclosed in which any suitable principles and advantages of the acoustic wave devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 9 to 11 are schematic block diagrams of illustrative packaged modules according to certain embodiments. Any suitable combination of features of these packaged modules can be implemented with each other.

FIG. 9 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include an acoustic wave filter that includes a plurality of acoustic wave devices, for example. The acoustic wave devices can be BAW devices in certain applications.

The acoustic wave component 172 shown in FIG. 9 includes one or more acoustic wave devices 174 and terminals 175A and 175B. The one or more acoustic wave devices 174 include at least one acoustic wave device implemented in accordance with any suitable principles and advantages disclosed herein. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 9. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more radio frequency (RF) couplers, one or more delay lines, one or more phase shifters, the like, or any suitable combination thereof. Accordingly, the other circuitry 173 can include one or more radio frequency circuit elements. The other circuitry 173 can be radio frequency circuitry. The other circuitry 173 can be electrically connected to the one or more acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 10 is a schematic block diagram of a module 200 that includes filters 202A to 202N, a radio frequency switch 204, and a low noise amplifier 206 according to an embodiment. One or more filters of the filters 202A to 202N can include any suitable number of acoustic wave devices in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

FIG. 11 is a schematic diagram of a radio frequency module 210 that includes an acoustic wave filter according to an embodiment. As illustrated, the radio frequency module 210 includes duplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 11 and/or additional elements. The radio frequency module 210 may include any one of the acoustic wave filters that include at least one acoustic wave resonator in accordance with any suitable principles and advantages disclosed herein.

The duplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave device in accordance with any suitable principles and advantages disclosed herein. Similarly, one or more of the receive filters can include an acoustic wave device in accordance with any suitable principles and advantages disclosed herein. Although FIG. 11 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the duplexers 181A to 181N. In some instances, the radio frequency switch 194 can electrically connect the output of the power amplifier 192 to more than one of the transmit filters. The antenna switch 182 can selectively couple a signal from one or more of the duplexers 181A to 181N to an antenna port ANT. The duplexers 181A to 181N can be associated with different frequency bands and/or different modes of operation (e.g., different power modes, different signaling modes, etc.).

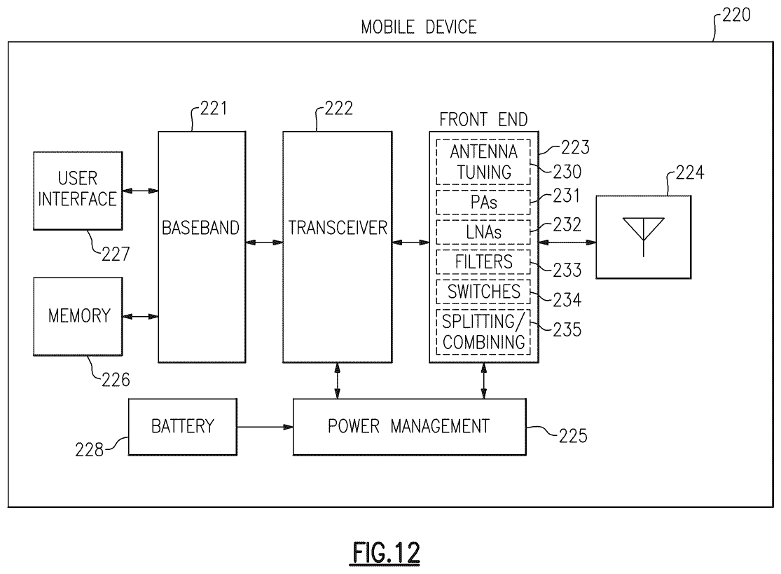

The acoustic wave devices disclosed herein can be implemented in wireless communication devices. FIG. 12 is a schematic block diagram of a wireless communication device 220 that includes an acoustic wave device according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 12 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 12, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 12, the power management system 225 receives a battery voltage from the battery 228. The battery 228 can be any suitable battery for use in the wireless communication device 220, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in a frequency range from about 2 GHz to 10 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main active region and a frame region, the bulk acoustic wave device comprising:
a first electrode;
a second electrode;
a piezoelectric layer between the first electrode and the second electrode; and
a conductive layer between the second electrode and the piezoelectric layer at least in the frame region, the conductive layer electrically connected to the first electrode and electrically isolated from the second electrode.

2. The bulk acoustic wave device of claim 1 wherein the frame region includes a frame structure, the frame structure includes a raised frame structure at least partially defined by the conductive layer.

3. The bulk acoustic wave device of claim 2 wherein the raised frame structure further includes a dielectric layer.

4. The bulk acoustic wave device of claim 2 wherein the frame structure further includes a recessed frame structure between the main active region and the raised frame structure.

5. The bulk acoustic wave device of claim 1 further comprising an acoustic wave reflector at least in the main active region.

6. The bulk acoustic wave device of claim 5 wherein the frame region at least partially overlaps the acoustic wave reflector.

7. The bulk acoustic wave device of claim 5 wherein the acoustic wave reflector includes an air cavity.

8. The bulk acoustic wave device of claim 5 wherein the acoustic wave reflector includes a Bragg reflector.

9. The bulk acoustic wave device of claim 1 wherein the conductive layer is in contact with the piezoelectric layer in the frame region and the second electrode is in contact with the piezoelectric layer in the main active region.

10. A radio frequency module comprising a filter having a bulk acoustic wave device of claim 1, radio frequency circuitry, and a package structure enclosing the filter and the radio frequency circuitry.

11. A bulk acoustic wave device having a main active region and a frame region, the bulk acoustic wave device comprising:
a first electrode;
a second electrode;
a piezoelectric layer between the first electrode and the second electrode; and
a conductive layer between the second electrode and the piezoelectric layer at least in the frame region, the conductive layer electrically isolated from the second electrode, the conductive layer and the first electrode having a first electrical polarity and the second electrode having a second electrical polarity.

12. The bulk acoustic wave device of claim 10 wherein the frame region includes a frame structure, the frame structure includes a raised frame structure at least partially defined by the conductive layer.

13. A bulk acoustic wave device having a main active region and a frame region, the bulk acoustic wave device comprising:
a first electrode;
a second electrode;
a piezoelectric layer between the first electrode and the second electrode;
a first conductive layer in a first portion of the frame region, the first conductive layer electrically connected to the first electrode and the piezoelectric layer in the first portion of the frame region being positioned between the first electrode and the first conductive layer; and
a second conductive layer in a second portion of the frame region, the second conductive layer electrically connected to the second electrode and the piezoelectric layer in the second portion of the frame region being positioned between the second electrode and the second conductive layer.

14. The bulk acoustic wave device of claim 13 wherein the first portion of the frame region includes a first frame structure, and the second portion of the frame region includes a second frame structure.

15. The bulk acoustic wave device of claim 14 wherein the first frame structure includes the first conductive layer, and the second frame structure includes the second conductive layer.

16. The bulk acoustic wave device of claim 15 wherein the first frame structure includes a thin portion of the second electrode thinner than a thickness of the second electrode in the main active region.

17. The bulk acoustic wave device of claim 15 wherein the first frame structure includes a first insulating material positioned between the second electrode and the first conductive layer, and the second frame structure includes a second insulating material positioned between the first electrode and the second conductive layer.

18. The bulk acoustic wave device of claim 13 further comprising an acoustic wave reflector at least in the main active region.

19. The bulk acoustic wave device of claim 18 wherein the frame region at least partially overlaps the acoustic wave reflector.

20. A radio frequency module comprising a filter having a bulk acoustic wave device of claim 13, radio frequency circuitry, and a package structure enclosing the filter and the radio frequency circuitry.
